(19) United States
(12) Patent Application Publication
(10) Pub. No.: US 2025/0096005 A1
(43) Pub. Date: Mar. 20, 2025

(54) METHODS FOR GLOBAL PLANARIZATION

(71) Applicant: Brewer Science, Inc., Rolla, MO (US)

(72) Inventors: Jinhua Dai, Rolla, MO (US); Joyce A. Lowes, Rosebud, MO (US); Daniel Patrick Sweat, Rolla, MO (US)

(21) Appl. No.: 18/890,144

(22) Filed: Sep. 19, 2024

Related U.S. Application Data
(60) Provisional application No. 63/539,587, filed on Sep. 20, 2023.

(51) Int. Cl. H01L 21/3105; H01L 21/02; H01L 21/027; H01L 21/32

(52) U.S. Cl. CPC H01L 21/31051; H01L 21/02255; H01L 21/0271; H01L 21/32

(57) ABSTRACT

Compositions and methods for global planarization of microelectronic substrates are provided. The methods include applying a crosslinking modifier composition to the surface of a substrate, or to any intermediate layer(s) on the substrate surface. A planarizing material can then be applied to the crosslinking modifier layer, which influences the degree of crosslinking in the planarizing layer. Depending on the specific topography of the underlying substrate (or intermediate layer), different amounts of planarizing material are removed during a subsequent develop back step, thereby eliminating bias that usually exists between regions of varying topographic density. The result is an effective global planarization method that is both time and cost efficient.

### CROSS-REFERENCE TO RELATED APPLICATIONS

The present application claims the priority benefit of U.S. Provisional Patent Application Ser. No. 63/539,587, filed on Sep. 20, 2023, entitled METHODS OF GLOBAL PLANARIZATION, the entirety of which is incorporated by reference herein.

### BACKGROUND

### Field

The present disclosure relates broadly to methods of fabricating microelectronic structures and, in particular, it relates to compositions and methods for global planarization of substrates during photolithography.

### Description of Related Art

In microelectronic device fabrication, integrated circuits and other semiconductor devices are often made by building layered structures in sequential, bottom-up manufacturing processes. For example, chips used in computers and other devices are often made this way. Various deposition, etching, and other processes can be used to make the layered features. Reliable devices require extremely close tolerances. Meeting these tolerances as each successive layer is built on top of the underlying layers requires the ability to achieve a highly-planarized upper surface on which to build subsequent layers.

For example, photolithographic techniques often involve patterning multiple stacked layers. As industry standards move to smaller and smaller patterned features, the requirements for precision and accuracy become more and more stringent. Accurate focusing of a patterned image on the surface being patterned can be impaired at each stage by surface unevenness. Moreover, the increasingly limited depth of focus associated with the use of smaller wavelength light and higher numerical aperture optics required to achieve very small features exacerbate the problem, magnifying the effects of even slight imperfections. As each successive layer is produced and patterned, creating a uniform, planar material on top of it becomes increasingly difficult, especially when the underlying layers have high-aspect-ratio topography such as deep trenches and/or vias.

Chemical mechanical polishing (CMP) can be used to planarize semiconductor device layers, but CMP is time consuming and adds to the expense of device manufacture. CMP also involves contacting the upper surface with a rotating polishing pad. Poor adhesion between surface layers and the underlying layer or layers and insufficient strength of materials to withstand the CMP process make it difficult to achieve the desired results. Moreover, CMP can also introduce contamination and other undesirable defects.

Another planarization method is to apply a thick coating of planarizing material over the topographic structures to obtain a planar top surface. However, a large overburden is undesirable for further processing steps. Other planarizing materials and processes require multiple additional steps such as reflow baking or plasma etch back to achieve planarization without leaving an excess overburden on top of the structures. Even with the extra steps and added costs, the results of this method can be improved.

Planarization can refer to local planarization or global planarization. Local planarization refers to flatness of the upper surfaces of smaller regions within a substrate having a substantially larger area. Global planarization refers to the flatness of the upper surface of the entire device-yielding area of the substrate. Efforts to achieve local planarization to date include adjustment of a polymer composition to change its properties (e.g., viscosity, surface tension, and/or thickness), as well as selection of various spin-coating parameters (e.g., ramp rate, spin speed, and spin times) to facilitate flow of the material from higher-level areas to lower-level areas. These have been moderately successful in achieving sufficient local planarization, but global planarization (without extra polishing steps) has not successfully been achieved on a commercial scale. Thus, there remains a need for improved methods of global planarization using spin-coated materials in the fabrication of microelectronic devices.

### SUMMARY

The present disclosure is broadly concerned with a method for forming a structure, comprising: providing a substrate comprising a substrate surface; optionally forming one or more intermediate layers on the substrate surface, wherein the substrate surface, or an uppermost surface of a top intermediate layer on the substrate surface if the one or more intermediate layers are present, comprises a first region of dense topographic features and a second region of isolated topographic features; applying a crosslinking modifier composition to the substrate surface or to the uppermost surface of the top intermediate layer, if present, to form a crosslinking modifier layer, the crosslinking modifier layer covering at least a portion of the first region of dense topographic features and at least a portion of the second region of isolated topographic features; applying a planarizing composition on the crosslinking modifier layer; heating the planarizing composition to form a planarizing layer having a first average thickness in the first region of dense topographic features and a second average thickness in the second region of isolated topographic features; and contacting the planarizing layer with a solvent to reduce the first average thickness and the second average thickness, wherein the contacting reduces the first average thickness more than the second average thickness.

The present disclosure is broadly concerned with a method for forming a structure, comprising: optionally forming one or more intermediate layers on a surface of a substrate, wherein the substrate surface, or an uppermost surface of a top intermediate layer on the substrate surface if the one or more intermediate layers are present, comprises a first region of dense topographic features and a second region of isolated topographic features on the substrate surface or on the uppermost surface of the top intermediate layer, if present, the crosslinking modifier layer covering at least a portion of the first region of dense topographic features and at least a portion of the second region of isolated topographic features; applying a planarizing composition on the crosslinking modifier layer, the planarizing composition comprising one or both of a crosslinkable polymer or a de-crosslinkable polymer; heating the planarizing composition to form a planarizing layer on the crosslinking modifier layer, wherein during the heating, a crosslinking modification component is generated in situ within the crosslinking modifier layer; and permitting at least a portion of the crosslinking modification component to contact the planarizing layer, the crosslinking modification component contacting the planarizing layer: (1) decreases the degree of crosslinking that the crosslinkable polymer would have undergone during said heating if said crosslinking modification component were not generated in said crosslinking modifier layer; and/or (2) de-crosslinks at least some of the de-crosslinkable polymer in the planarizing layer.

The present disclosure is broadly concerned with a structure comprising a substrate having a substrate surface; one or more intermediate layers optionally present on the substrate surface, wherein the substrate surface or an uppermost surface of a top intermediate layer on the substrate surface if present, comprises a first region of dense topographic features and a second region of isolated topographic features; a crosslinking modifier layer on at least a portion of the substrate surface or the uppermost surface of the top intermediate layer, if present; and a non-patterned planarizing layer on at least a portion of the crosslinking modifier layer, the non-patterned planarizing layer being crosslinked throughout at least 95% of its volume, and wherein the non-patterned planarizing layer has a bias measured between the first region of dense topographic features and the second region of isolated topographic features that is less than 30 nm.

### BRIEF DESCRIPTION OF THE DRAWINGS

FIGURE (FIG. 1 is a schematic diagram (not to scale) showing some embodiments of a lithography stack utilizing the global planarizing compositions and methods described herein;

FIG. 2 is a schematic diagram (not to scale) showing some embodiments of a lithography stack utilizing the disclosed global planarizing compositions and methods;

FIG. 3a is a schematic diagram (not to scale) showing some embodiments of a substrate having different topographic regions and a layer of global planarizing composition applied to each of the regions used to formulate equations for predicting bias as described in Example 9;

FIG. 3b is a cross-sectional SEM photograph showing a planarizing layer applied to a substrate having several different topographic regions used to validate equations for predicting bias as described in Example 9;

FIG. 4 provides several images of a chip having different topographic regions, including a top view (bottom left) and an enlarged plan view (bottom right) of the chip, as well as cross-sections of different topographic regions (top);

FIG. 5 provides several cross-sectional SEM photographs of two different topographic regions on a substrate during various steps of the planarization method described in Example 4;

FIG. 6 provides several cross-sectional SEM photographs of different topographic regions on several substrates formed as described in Example 5;

FIG. 7 provides several cross-sectional SEM photographs of different topographic regions on several substrates formed as described in Example 6;

FIG. 8 provides several cross-sectional SEM photographs of different topographic regions on two different substrates formed as described in Example 7; and

FIG. 9 provides several cross-sectional SEM photographs of different topographic regions on two different substrates formed as described in Example 8.

### DETAILED DESCRIPTION

The present disclosure is broadly concerned with novel crosslinking modifier compositions and methods of using those compositions to achieve global planarization of microelectronic structures used for photolithography.

### COMPOSITIONS

### 1. Composition for Crosslinking Modifier Layer

The crosslinking modifier layer may comprise at least one polymer capable of generating a crosslinking modification component. Preferred polymers for use in crosslinking modifier compositions can be acid- or base-generating polymers. Such polymers comprise recurring monomers that include acid- or base-generating monomers, surface adhesion monomers, and solubility-enhancing monomers.

When the polymer used in the crosslinking modifier composition is a base-generating polymer, it includes at least one monomer comprising a base-generating functional group. The base-generating functional group is any group that is base itself (such as pyridine) or is capable of forming a base when exposed to heating (e.g., a thermal base generator, or “TBG”) or light (e.g., a photo base generator, or “PBG”). In both cases, the PBG or TBG groups may be bonded to the monomer and may considered part of its structure (and, ultimately, may be part of the polymer structure as a pendant group and/or part of the polymeric backbone). In some embodiments, the crosslinking modifier composition can comprise less than about 0.5, preferably less than about 0.1, or more preferably less than about 0.01% by weight of a TBG or PBG compound separate from (i.e., unbound or not bonded to) the base-generating polymer.

Examples of such base-generating functional groups include those chosen from amines, including C₁ to C₁₂, and more preferably C₁ to C₆, aliphatic amines, and C₅ to C₁₈, and more preferably, C₆ to C₁₆ aromatic and/or heteroaromatic amines, or combinations thereof. Preferred heteroaromatic amines are six- to eighteen-membered rings, and more preferably six- to twelve-membered rings. Examples of specific base-generating amine functional groups suitable for use in various embodiments of the present technology include, but are not limited to, hexylamine, monoethanolamine, 2-aminoethyl methacrylate hydrochloride, methacryloyl-L-Lysine, N-[3-(N,N-Ddmethylamino) propyl]methacrylamide, N-[2-(N,N-dimethylamino)ethyl]methacrylamide, N-[3-(N,N-dimethylamino) propyl]acrylamide, 2-(N,N-dimethylamino)ethyl acrylate, 2-(N,N-diethylamino)ethyl methacrylate, 2-(N,N-dimethylamino)ethyl methacrylate, pyridine, vinylpyridine, aniline, 4,4′-oxydianiline, or combinations thereof.

Examples of suitable monomers to which the base-generating functional group may be attached to provide the base-generating monomer can include, but are not limited to, those chosen from acrylates, methacrylates, acrylamides, amides, aromatic amines and diamines, dianhydrides, acrylonitriles, esters, or combinations thereof.

When used, the base-generating monomer is preferably present in the polymer at a level of from about 0.5% to about 100%, preferably about 1% to about 50%, more preferably about 1% to about 20%, or more preferably about 1.5% to about 12.5%, or most preferably about 1% to about 10%, based on the total weight of the polymer taken as 100%.

When the polymer used in the crosslinking modifier composition is an acid-generating polymer, it may comprise recurring monomers that include an acid-generating functional group. Examples of suitable acid-generating functional groups include photoacid generator (“PAG”) functional groups or thermal acid generator (“TAG”) functional groups. PAG functional groups are those that generate an acid upon exposure to light at the target wavelength(s), while TAG groups are those that generate an acid when exposed to heat. In both cases, the PAG or TAG groups may be bonded to the monomer and are considered part of its structure (and, ultimately, may be part of the polymer structure as a pendant group and/or part of the polymeric backbone). In some embodiments, the crosslinking modifier composition can comprise less than about 0.5%, preferably less than about 0.1%, or more preferably less than about 0.01% by weight of a TAG or PAG compound separate from (i.e., unbound or not bonded to) the acid-generating polymer.

Examples of suitable PAG functional groups may be chosen from onium salts (e.g., triphenyl sulfonium (“TPS”) perfluorosulfonates such as TPS nonaflate, TPS triflate); substituted forms of onium salts (e.g., alkyl-substituted TPS nonaflate (preferably C₁-C₈-substituted); tris(4-tert-butylphenyl) sulfonium perfluoro-1-butanesulfonate); oxime-sulfonates (e.g., Irgacure PAG 203, CGI PAG 19XX, N-hydroxynaphthalimide triflate, N-hydroxy-5-norbornene-2,3-dicarboximide perfluoro-1-butanesulfonate); triazines (e.g., 2-methyl-2-(2′-furylethylidene)-4,6-bis(trichloromethyl)-1,3,5-triazine, 2-[(4′-methoxy) styryl]-4,6-bis(trichloromethyl)-1,3,5-triazine); or combinations thereof. Suitable TAG functional groups may be chosen from ionic TAG functional groups such as quaternary or tertiary ammonium blocked sulfuric (including fluorinated) acid, non-ionic TAG functional groups such as N-Hydroxynaphthalimide sulfonic acid esters, or combinations thereof.

The foregoing acid functional groups (e.g., TAG or PAG groups) can be substituted onto (e.g., bonded with) one or more monomers chosen from acrylates, methacrylates, acrylamides, amides, aromatic amines and diamines, dianhydrides, acrylonitriles, esters, or combinations thereof. These monomers, bonded to one or more TAG or PAG groups, form acid-generating monomers that can be used to form polymers as described herein.

Examples of especially preferred acid-generating monomers include triphenylsulfonium 3-sulfopropyl methacrylate (“TPS-SPMA,” the middle monomer of Polymer B below) and triphenylsulfonium 4-(methacryloxy)-2,3,5,6-tetrafluoro benzenesulfonate (“TPS-4FBSMA,” the middle monomer of Polymer C below). The acid-generating monomers can be prepared according to methods disclosed in U.S. Pat. No. 8,900,792, the entirety of which is incorporated by reference herein to the extent not inconsistent with the present disclosure.

The acid-generating monomer, when used to form polymers for a crosslinking modifier composition, may preferably be present in the polymer at a level of from about 0.1% to about 99% by weight, preferably from about 0.5% to about 35% by weight, preferably about 0.5% to about 20% by weight, more preferably from about 1% to about 10% by weight, based on the total weight of the polymer taken as 100%.

In some embodiments, the polymer used in the crosslinking modifier composition may also comprise at least one surface adhesion monomer. Such monomers can help facilitate adhesion (or surface bonding) of the polymer to the surface on which it is applied. Suitable surface adhesion monomers include functional groups able to chemically or physically interact with the substrate surface (or upper surface of the topmost intermediate layer, when present) to which the composition is applied. Thus, it will be appreciated that different surface adhesion monomers may be used for different surfaces.

Preferred surface adhesion monomers include those functional groups or moieties chosen from hydroxys (such as 2-hydroxyethyl methacrylate and/or hydroxypropyl methacrylate); epoxies (such as glycidyl methacrylate); carboxylic acids (such as methacrylic acid, acrylic acid, and/or mono-2-(methacryloyloxy)ethyl succinate); thiols (such as 2-(methylthio)ethyl methacrylate); silanes (such as 3-(trimethoxysilyl) propyl methacrylate); aldehydes (such as 3-[(4-ethenylphenyl) methoxy]-benzaldehyde); acetylacetonates (such as 2-(methacryloyloxy)ethyl acetoacetate); or combinations of one or more of the foregoing.

The surface adhesion monomer is preferably present in the polymer at a level of from about 1 to about 99% by weight, preferably about 2 to about 50% by weight, more preferably about 3 to about 25% by weight, more preferably about 5 to about 20% by weight, or even more preferably about 7.5 to about 15% by weight, based on the total weight of the polymer taken as 100%.

In some embodiments, the polymers used in crosslinking modifier compositions can further comprise a solubility-enhancing monomer, which may be useful if the chosen acid- or base-generating monomer is not readily dissolvable in the chosen solvent. The solubility-enhancing monomer, which may be inert, can have a further or alternative function of moderating or controlling the amount of acid or base generated by the polymer. Inclusion of higher levels of solubility-enhancing monomer in the polymer can reduce the amount of acid or base generated. Preferred solubility-enhancing monomers can be chosen from styrene, methyl methacrylate, methyl styrene, 4-tert-butylstyrene, n-butyl methacrylate, benzyl methacrylate, or combinations thereof.

When utilized in an acid-generating polymer, the solubility-enhancing monomer can be present in the polymer at a level of from about 1% to about 90% by weight of the polymer, preferably from about 10% to about 80% by weight of the polymer, more preferably from about 20% to 70%, or even more preferably from about 25% to about 65%, based on the total weight of the polymer taken as 100%.

When utilized in a base-generating polymer, the solubility-enhancing monomer may be present at a level of from about 0% to about 99%, preferably from about 30% to about 95%, or more preferably from about 50% to about 95%, or even more preferably from about 55% to about 90%, based on the total weight of the polymer taken as 100%.

Although the polymer can include other monomers in addition to acid- or base-generating monomers, the surface adhesion monomers, and the solubility-enhancing monomers, in some embodiments, the polymer consists essentially of, or even consists of, only these three types of monomers. Thus, the polymer may include other monomers in an amount of less than about 1% by weight, less than about 0.5% by weight, or less than about 0.1% by weight, based on the total weight of the polymer taken as 100%.

The polymer containing the foregoing monomers can be synthesized by any suitable polymerization method, with one preferred polymerization method being free radical polymerization. In one preferred embodiment, the polymer is synthesized via free radical polymerization in a solvent such as propylene glycol monomethyl ether (PGME) using azobisisobutyronitrile (AIBN) as an initiator. The radical polymerization is preferably performed using an initiator in an amount of from about 1% to about 5% by weight, more preferably about 2% by weight of the monomers and allowing the polymerization to proceed at a temperature 60° C. to 90° C., or more preferably about 60 to about 75° C. for about 4 hours to about 24 hours, or about 8 hours to about 20 hours.

A preferred base-generating polymer suitable for use in a crosslinking modifier composition according to embodiments of the present technology is shown as Polymer A, below.

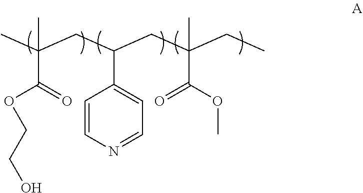

Polymer A is formed using recurring monomers of 2-hydroxyethylmethacrylate (“HEMA”), 4-vinylpyridine, and methyl methacrylate. Polymer A preferably comprises HEMA monomers at a level of from about 5% to about 25% by weight (or more preferably about 7.5% to about 15% by weight); 4-vinylpyridine monomers at a level of about 1% to about 15% by weight (or more preferably about 1.5% to about 12.5% by weight); and methyl methacrylate monomers at a level of about 65% to about 95% by weight (or more preferably about 75% to about 90% by weight), all based on the total weight of the polymer taken as 100%.

Two preferred acid-generating polymers suitable for use in a crosslinking modifier composition according to embodiments of the present technology are shown as Polymers B and C, below.

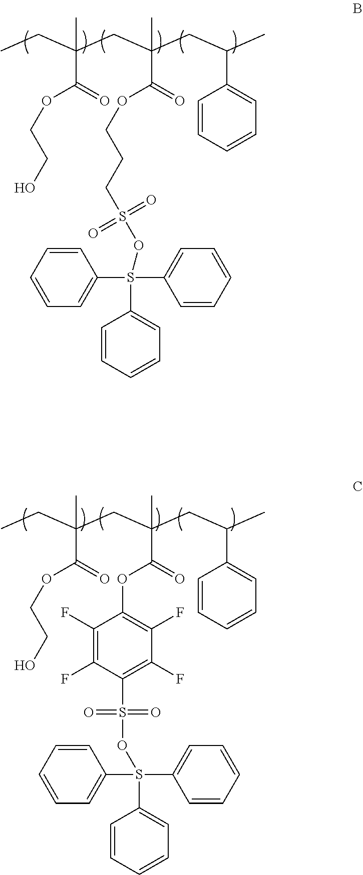

Polymer B comprises recurring monomers of HEMA, styrene, and TPS-SPMA, and Polymer C comprises recurring monomers of HEMA, styrene, and TPS-4FBSMA. With either Polymer B or C, the polymer preferably comprises from about 1% to about 20% by weight of the HEMA monomer (and more preferably from about 5% to 10% by weight); from about 1% to 90% by weight of the styrene monomer (and more preferably from about 40% to about 60%); and from about 5% to about 95% by weight of the PAG-containing monomer (TPS-SPMA and/or TPS-4FBSMA; more preferably from about 40% to about 60% by weight), all based on the total weight of the polymer taken as 100%.

The weight-average molecular weight (Mw) range (as measured by gel permeation chromatography) of the polymer is preferably from about 3,000 to about 50,000 g/mol, about 4,000 to about 40,000 g/mol, about 5,000 to about 30,000 g/mol, or about 6,000 to about 20,000 g/mol.

Crosslinking modifier compositions for use according to embodiments of the present invention include at least one acid- or base-generating polymer, as discussed previously, dispersed or dissolved in a solvent system. In some embodiments, the solvent system used in the crosslinking modifier composition has a boiling point of from about 70° C. to about 200° C., and more preferably from about 100° C. to about 150° C. Preferred solvent systems for use in forming the crosslinking modifier composition include a solvent chosen from propylene glycol monomethyl ether acetate (PGMEA), PGME, propylene glycol n-propyl ether (PnP), ethyl lactate (EL), cyclohexanone, gamma-butyrolactone (GBL), methyl isobutyl carbinol, propylene glycol ethyl ether (PGEE), n-butyl acetate, or mixtures thereof.

The solvent system can preferably be utilized at a level of from about 95% to about 99.5% by weight, and more preferably from about 98% to about 99% by weight, based upon the total weight of the crosslinking modifier composition taken as 100% by weight, with the balance of the foregoing being attributable to the solids in the composition, which will generally be entirely the polymer discussed above. In the latter instance, the polymer may be present in the composition at a level of from about 1% to about 10% by weight, and preferably from about 2% to about 5% by weight, based upon the total weight of the composition taken as 100% by weight. In some embodiments, the composition has a total solids content, and the polymer is at least from about 99.5% to about 100% of the total solids content, and even more preferably about 100% of the total solids content.

Suitable compositions can be formed by mixing the acid- or base-generating polymer with a solvent system under ambient conditions. Any optional ingredients (e.g., surfactants, catalysts, and/or other additives) could be mixed at the same time.

The acid- or base-generating polymers in the crosslinking modifier compositions are capable of generating a crosslinking modification component (e.g., an acid or a base) that diffuses into, or otherwise interacts with, the overlying layer in order to interfere with the degree of crosslinking in the adjacent layer (e.g., reducing existing crosslinking or inhibiting or preventing new crosslinking). The specific composition of the crosslinking modifier composition (and resulting crosslinking modifier layer) can be selected to effectively modify the degree of crosslinking of an adjacent layer, as discussed in further detail below.

### 2. Compositions for Planarizing Layer

The planarizing layer composition may comprise at least one crosslinkable polymer dispersed or dissolved in a solvent system. The polymer(s) can be present in an amount of from about 0.1% to about 20% by weight, preferably from about 0.5% to about 10% by weight, and more preferably from about 1% to about 5% by weight, based upon the total weight of the composition taken as 100% by weight.

In some embodiments, the polymer(s) may be selected so that the planarizing layer is a carbon-rich layer. As used herein, the term “carbon-rich” refers to layers formed from compositions comprising from about 50% to about 99% by weight carbon, preferably from about 70% to about 90% by weight carbon, and more preferably from about 75% to about 80% by weight carbon, based upon the total solids in the composition taken as 100% by weight. The specific polymer used in the carbon-rich layer can vary but is selected to achieve the carbon levels specified above. One having ordinary skill in the art can readily calculate this percentage based upon the chemical structure of the solids included in the composition. Alternatively, the carbon atom and total atom contents can be analyzed and calculated using known analytical equipment, including x-ray fluorescence spectroscopy, auger spectroscopy, and secondary ion mass spectroscopy.

Specific examples of polymers for use in carbon-rich planarizing compositions (and layers) include, but are not limited to, any acid catalyzed cross-linkable polymers (with or without crosslinking agents) such as epoxy resins (e.g., Epiclon® epoxy resins, epoxy cresol novolac (ECN), commercial spin-on-carbon materials (e.g., OptiStack® SOC110 series material, Brewer Science, Inc), polyvinyl alcohols, and 2-hydroxyethyl methacrylate polymers.

In some embodiments, the planarizing layer may comprise at least one polymer having a high silicon content. For example, the polymer may comprise silicon in an amount of about 25 to about 50% by weight, or about 30 to about 45% by weight, or about 33 to about 40% by weight, based on the total weight of the polymer taken as 100%.

The planarizing composition can be a crosslinkable composition and, thus, may include at least one crosslinkable polymer. In some embodiments, the polymer used in the planarizing composition comprise an acid-crosslinkable (or acid catalyzed crosslinkable) polymer. Examples of such include, but are not limited to, polymers including recurring monomers with a functional group chosen from epoxy, vinyl ether, hydroxy, carboxylic acid, glycidyl, thiol, or combinations thereof. In some embodiments, the polymer used in the planarizing composition may comprise a base-crosslinkable (or base catalyzed crosslinkable) polymer.

Alternatively, the planarizing composition may include at least one polymer that can be un-crosslinked (i.e., is de-crosslinkable) via contact with an acid. Examples of such polymers include carboxylic acid containing polymers with vinyl ether crosslinker. Additionally, in some embodiments, the polymers utilized in the planarizing composition may include at least one polymer that can be un-crosslinked (i.e., is de-crosslinkable) via contact with a base.

In some embodiments, the planarizing composition may further comprise a separate crosslinking agent, while in other embodiments, the polymer(s) used in the planarizing composition may be self-crosslinkable (e.g., can have one or more crosslinkable groups incorporated into the polymer or polymers). When used, suitable crosslinking agents include those chosen from epoxy, melamine, and vinyl ether crosslinkers, such as MY721 (N,N,N′,N′-tetraglycidyl-4,4′-methylene-bisbenzenamine), Cymel® 303 (hexamethoxymethylmelamine), Powderlink™ 1174 [1,3,4,6-tetrakis-(methoxymethyl)glycoluril], ECN 1299 (epoxy cresol novolac resin), or Epon SU-8. In embodiments where a separate crosslinking agent is utilized, it is preferably included at levels of from about 5% to about 40% by weight, and preferably from about 10% to about 30% by weight, based upon the total weight of the composition taken as 100% by weight.

In some embodiments, a catalyst may be included to initiate crosslinking reactions. Suitable catalysts include acids or bases and may include one or more chosen from p-toluenesulfonic acid (pTSA), 5-sulfosalicylic acid (5-SSA), triphenylphosphine, bis(triphenylphosphoranylidene) ammonium chloride, tetrabutylphosphonium bromide, and ethyltriphenylphosphonium acetate, benzyltriethylammonium chloride (BTEAC), and tetramethylammonium hydroxide (TMAH). Specific examples include thermal acid generators (TAG), such as TAG2678 and TAG 2689 (commercially available from King Industries in Norwalk, Connecticut. Unlike the acid- or base-generating functional groups discussed previously with respect to the crosslinking modifier composition, the catalyst included in the planarizing composition (or layer) may not be bound to the polymer itself, but, instead, may be added separately to promote the crosslinking reaction.

When a catalyst is used in the planarizing composition, it is preferably included in the planarizing composition at levels of from about 0.5% to about 5% by weight, and preferably from about 1% to about 3% by weight, based upon the total weight of the composition taken as 100% by weight.

The solvent system used in the planarizing composition may comprise a solvent chosen from PGMEA, PGME, cyclohexane, isopropanol, n-butyl acetate, or combinations thereof. The solvent system can be utilized at a level of from about 80% to about 99.9% by weight, and more preferably from about 95% to about 99% by weight, based on the total weight of the composition taken as 100% by weight, with the balance of the composition being attributable to the solids in the composition. The planarizing composition could also include a number of other optional ingredients. Typical optional ingredients include those chosen from surfactants, adhesion promoters, or mixtures thereof.

Regardless of the embodiment, the planarizing compositions may be formed by simply dispersing or dissolving the polymer and any other ingredients as described above, in the solvent system, preferably at ambient conditions and for enough time to form a substantially homogeneous dispersion.

### Methods of Using the Crosslinking Modifier and Planarizing Compositions

Referring to FIG. 1(A), a stack 10 is schematically depicted. Stack 10 comprises a substrate 12 having a surface 14.

Substrate 12 comprises any suitable type of microelectronic substrate, and preferably is a semiconductor substrate. Exemplary types of substrates may be chosen from silicon, SiGe, SiO₂, Si₃N₄, SiON, SiCO:H (such as that sold under the name Black Diamond, by SVM, Santa Clara, CA, US), tetramethyl silate and tetramethyl-cyclotetrasiloxane combinations (such as that sold under the name CORAL), aluminum, tungsten, tungsten silicide, gallium arsenide, germanium, tantalum, tantalum nitride, Ti₃N₄, hafnium, HfO₂, ruthenium, indium phosphide, glass, or combinations of the foregoing.

Optional intermediate layers (not shown) may also be formed on the surface 14 of substrate 12 prior to processing. Examples of optional intermediate layers include, but are not limited to, silicon, silicon dioxide, silicon carbide, silicon nitride, silicon oxynitride, metals (including TiN and/or tungsten), carbon (including carbon fiber, carbon nanofibers, carbon nanotubes, diamond, and/or graphene), fluorocarbons, filaments, and high-k dielectrics. One or more, or none, of these intermediate layers may be present on the surface 14 of substrate 12.

As shown in FIG. 1(A), the substrate 12 has a non-planar surface 14 that includes one or more regions of topography on its surface. As used herein, “topography” refers to the height or depth of a structure in or on substrate surface 14. Examples of specific topographic features include, but are not limited to, contact holes, via holes, raised features, raised lines, and/or trenches. The topography can be included directly on the substrate surface 14, or it can be included in one or more layers of other material (not shown) formed on the substrate surface 14, such as the optional intermediate layers described above.

As shown in FIG. 1(A), the surface 14 of substrate 12 has both a first region of dense topographic features (i.e., a “dense region”) 16a and a second region of isolated topographic features (i.e., an “isolated region”) 16b. As used herein, the term “dense region” as it relates to substrate topography refers to a region on the surface of the substrate (or intermediate layers formed thereon) that has a pitch-to-line ratio (P) of about 4:1 or less. The P of dense regions is preferably in the range of about 0.5:1 to 3.5:1, about 1:1 to about 3:1, or about 1.5:1 to about 2.75:1. Conversely, the term “isolated region” or “iso region,” as it relates to surface topography, refers to a region on the surface of a substrate (or intermediate layers formed thereon) having a P of greater than 4:1. Isolated regions may have a P in the range of about 4.5:1 to about 14:1, about 5:1 to about 12:1, or about 6:1 to about 10:1. As shown in FIG. 1(A), the dense region 16a has a higher density of topographic features relative to the isolated region 16b.

As indicated by the break lines in FIG. 1(A), the dense and isolated regions 16a,b can be spaced apart from one another at various locations on the substrate surface 14. A single substrate surface 14 (or upper surface of the topmost intermediate layer, if present) can include multiple dense and/or isolated regions spaced over the entire surface 14 of the substrate 12.

Turning now to FIG. 1(B), a crosslinking modifier composition may be applied to the surface 14 of the substrate 12 (or on the uppermost surface of the topmost intermediate layer, if present) and treated to form a crosslinking modifier layer 18. The crosslinking modifier composition may be applied by any known method, with a preferred method being spin coating. When spin coating is used, it may include a ramp speed of preferably from about 500 to about 15,000 rpm/s, and more preferably about 1,000 to about 12,000 rpm/s and a spin speed of preferably from about 500 rpm to about 5,000 rpm, and more preferably about 1,000 to about 1,750 rpm, for a time period of preferably from about 30 seconds to about 120 seconds, or more preferably from about 45 seconds to about 75 seconds, followed by baking. Preferred baking conditions comprise heating at temperatures preferably from about 100° C. to about 300° C., more preferably from about 130° C. to about 250° C., even more preferably from about 150° C. to about 215° C., or most preferably from about 160° C. to about 205° C., for a time period of preferably from about 30 seconds to about 300 seconds, or more preferably from about 45 seconds to about 75 seconds to form the crosslinking modifier layer 18.

Optionally, a solvent may be used to wash the crosslinking modifier layer 18 to remove any unbound polymer residue. Suitable wash solvents include, for example, polar solvents such as PGMEA, PGME, methyl isobutyl ketone (MIBK), cyclohexanone, ethyl lactate, dimethylacetamide, and/or tetrahydrofurfuryl alcohol. The solvent washing step may be carried out using puddling or dynamic washing methods. When puddling is used, it may be carried out for a time period of preferably from about 10 seconds to about 120 seconds, and more preferably from about 15 seconds to about 90 seconds.

Residual solvent is removed by an optional spinning step, followed by a dry bake step. The drying spin step is preferably carried out at speeds of from about 100 rpm to about 3,000 rpm, and more preferably from about 1,250 rpm to about 1,750 rpm, for a time period of preferably from about 30 seconds to about 120 seconds, and more preferably from about 45 seconds to about 75 seconds. Preferred baking conditions for the dry bake step can involve temperatures of from about 90° C. to about 200° C., and more preferably from about 150° C. to about 210° C., for a time period of from about 30 seconds to about 120 seconds, and preferably from about 45 seconds to about 75 seconds.

The crosslinking modifier layer 18 may have a generally uniform thickness across the surface 14 of the substrate 12 (or the uppermost surface of the top intermediate layer, if present). The average thickness of the crosslinking modifier layer 18 can be in the range of from about 1 nm to about 10 nm, or preferably about 2 to about 8 nm. As generally shown in FIG. 1(B), the crosslinking modifier layer 18 can have a large degree of conformality with the surface 14 of the substrate 12 (or uppermost surface of the top intermediate layer, if present). Exact conformality is not required as long as the overall density of crosslinking modifier applied in each of the dense and isolated regions 16a,b is correlated with the topographic density of that region. In general, dense regions 16a have larger surface areas (due to the undulating topography), which results in a higher density of crosslinking modifier in these regions as compared to the isolated regions 16b, which have smaller surface areas and, consequently, lower density of crosslinking modifier.

In some embodiments, the crosslinking modifier layer 18 may have a low total thickness variation (TTV), meaning that the thinnest and thickest points of the layer 18 are not dramatically different from one another. The TTV of a given layer is preferably calculated by measuring the thickness at a number of points or locations on the layer, preferably at least about 50 points or at about 50 points, more preferably at least about 100 points or at about 100 points, and even more preferably at least about 1,000 points or at about 1,000 points. The difference between the highest and lowest thickness measurements obtained at these points is designated the TTV measurement for that particular layer. In some TTV measurement instances, edge exclusion or outliers may be removed from the calculation. In those cases, the number of included measurements is indicated by a percentage, that is, if a TTV is given at 97% inclusion, then 3% of the highest and lowest measurements are excluded, with the 3% split equally between the highest and lowest (i.e., 1.5% each). Preferably, the TTV ranges noted above are achieved using from about 95% to about 100% of the measurements, more preferably from about 97% to about 100% of the measurements, and even more preferably about 100% of the measurements.

In addition to a low TTV in terms of an absolute number (e.g., 5 pm), the TTV relative to the average film thickness of the crosslinking modifier layer 18 should be low. Thus, the crosslinking modifier layer 18 should have a TTV on a blank substrate of less than about 25% of the average thickness, preferably less than about 10% of the average thickness, and more preferably less than about 5% of the average thickness of the bonding layer 20. For example, if the crosslinking modifier layer 18 has an average thickness of 50 μm, the maximum acceptable TTV would be about 12.5 μm or lower (less than about 25% of 50 μm), preferably about 5 μm or lower (less than about 10% of 50 μm), and more preferably about 2.5 μm or lower (less than about 5% of 50 μm).

Turning now to FIG. 1(C), a planarizing composition formulated as described previously is coated on the crosslinking modifier layer 18 to form a planarizing layer 20. The planarizing composition can be applied by any known method, including spin-coating. When spin coating is used, the planarizing composition can be applied at a ramp speed in the range of preferably from about 500 to about 15,000 rpm/s, and more preferably from about 750 to about 8,000 rpm/s and a spin speed of preferably from about 500 rpm to about 5,000 rpm, and more preferably from about 1,000 to about 1,750 rpm, for a time period of preferably from about 30 seconds to about 120 seconds, and more preferably about 45 seconds to about 75 seconds, followed by baking. Preferred baking conditions comprise heating via hot plate baking at temperatures from about 100° C. to about 300° C., more preferably from about 130° C. to about 250° C., even more preferably from about 150° C. to about 215° C., and most preferably from about 160° C. to about 205° C., for a time period of about 30 seconds to about 300 seconds, and more preferably from about 45 seconds to about 75 seconds to provide the planarizing layer 20. The baking step also activates any catalysts present in the planarizing composition, which facilitates crosslinking of the planarizing layer 20. This may be particularly useful when the crosslinking modifier layer 18 includes a thermal base- or acid-generating group. According to embodiments in which the crosslinking modifier layer 18 comprises a photo base- or acid-generating group, an additional radiation exposure step may be included to activate the photo-generated acid or base within the crosslinking modifier layer 18.

As shown in FIG. 1(C), when applied to the surface 14 of the substrate 12 (or to the uppermost surface of the top intermediate layer, if present), the planarizing composition tends to accumulate in the dense region 16a of topographic features more than in the isolated region 16b. This can be due, in part, to the flow characteristics of the planarizing composition, as well as the topography of the substrate, since more planarizing composition is needed to fill isolated regions (e.g., region 16b) than is needed to fill more topographically dense regions (e.g., region 16a) to achieve a given layer thickness.

As shown in FIG. 1(C), because of the difference in accumulation of the planarizing material in the dense and isolated regions 16a,b, the thickness of the planarizing layer 20 is not uniform. As a result, a bias, B, develops between the two regions 16a, 16b. As used herein and unless otherwise noted, the term “bias” refers to the difference in average thickness of a layer in the dense region 16a and the isolated region 16b of a substrate. Typically, with conventional global planarization materials and methods, the bias can be in the range of about 35 nm to about 70 nm, or about 40 to about 60 nm.

The average thickness of a layer when determining bias is found by measuring (with an SEM photograph and imaging program (e.g., ImageJ) the thickness of a layer at a point about halfway between two topographic features that are not separated from one another by an intervening feature and whose boundaries are within about 1,000 nm of one another. These measurements are repeated over a wafer (or other area as defined herein) up to 49 times, and the measurements are averaged to determine the average thickness of a layer. The bias is then calculated by subtracting the average thickness of a layer over a dense region (16a in FIGS. 1(C) to (D)) from the average thickness of that same layer over an isolated region (16b in FIGS. 1(C) to (D)). Note that a negative value for bias in this case indicates that the thickness of the layer over the isolated region is greater than the thickness of the layer over the dense region.

According to some embodiments, the specific compositions of the crosslinking modifier layer 18 and the planarizing layer 20 may be selected so that after the crosslinking modification component has been generated within the crosslinking modifier layer 18, it can contact at least a portion of the overlying planarizing layer 20 so that the crosslinking modification component can interfere with (e.g., reduce or prevent) crosslinking within at least a portion of the planarizing layer 20. In some embodiments, at least a portion of the crosslinking modification component from the crosslinking modifier layer 18 may diffuse into at least a portion of the planarizing layer 20, wherein it may react with at least a portion of the crosslinked polymer or with a crosslinking agent or group present in that portion of the planarizing layer 20. In other embodiments, a crosslinking agent from the overlying planarizing layer 20 may diffuse into the crosslinking modifier layer 18 and react with the crosslinking modification component in that layer 18, thereby reducing the amount of crosslinking agent present in planarizing layer 20. In either case, the generation and presence of the crosslinking modification component in crosslinking modifier layer 18 reduces the degree of crosslinking in at least a portion of the planarizing layer 20 as compared to the degree of crosslinking that would have been present if the crosslinking modification component had not been generated or present in the crosslinking modifier layer 18.

According to some embodiments when the crosslinking modification component from the crosslinking modifier layer 18 diffuses into at least a portion of the planarizing layer 20, the crosslinking modification component may react with at least a portion of a crosslinking agent or group or a crosslinked polymer present in that portion of the planarizing layer 20. For example, if the planarizing layer 20 includes an acidic crosslinking agent and an acid-crosslinkable (acid-catalyzed crosslinkable) polymer, a base or base-containing compound may be used as the crosslinking modification component and can diffuse into the planarizing layer 20 to react with (neutralize) a portion of the acidic crosslinking agent therein. As a result, the degree of crosslinking in that portion of the planarizing layer 20 is less than it would have been if no crosslinking modification component had been present in crosslinking modifier layer 18. Similarly, if the planarizing layer 20 includes a basic crosslinking agent and a base-crosslinkable (base-catalyzed crosslinkable) polymer, an acid or acid-containing compound may be used as the crosslinking modification component. Similar acid/base composition schemes could also be employed in the crosslinking modifier layer 18 and the planarizing layer 20 when the planarizing layer 20 does not include a separate crosslinking agent, but instead includes acid- or base-crosslinkable groups incorporated onto into the polymer itself.

Alternatively, in some embodiments, the crosslinking modification component from the crosslinking modifier layer 18 may diffuse into the planarizing layer 20 and may de-crosslink at least some of a crosslinked polymer present in the planarizing layer 20. As discussed above, the crosslinking modification component may be selected to achieve a reduction in the degree of crosslinking in the planarizing layer 20. For example, when the crosslinked polymer is acid de-crosslinkable, the crosslinking modification component may be an acid or acid-containing compound. When the crosslinked polymer is base de-crosslinkable, the crosslinking modification component may be a base or base-containing compound. Thus, when the crosslinking modification component contacts or diffuses into at least a portion of the planarizing layer, it may de-crosslink at least some of the crosslinked polymer in that portion.

In still other embodiments, at least a portion of a crosslinking agent present in the planarizing layer 20 may contact or diffuse into a portion of the crosslinking modifier layer 18, wherein it may react with (e.g., be neutralized by) at least a portion of the crosslinking modification component present in that layer 18. In such embodiments, this reduces the overall amount of crosslinking agent present in at least a portion of the planarizing layer 20, which reduces the degree of crosslinking in that portion of the layer 20. Similarly to other embodiments, the crosslinking modification agent may be selected based on the type of crosslinking agent used in the planarizing layer 20 (or vice versa), such that an base or base-containing crosslinking modification component can be used in the crosslinking modifier layer 18 to neutralize an acidic crosslinking agent from planarizing layer 20, and an acid or acid-containing crosslinking modification component can be used in layer 18 to neutralize a basic crosslinking agent present in planarizing layer 20.

To the extent the crosslinking agent of the planarizing layer 20 is neutralized by the crosslinking modification component modifier layer 18 and/or to the extent that the crosslinked polymer in planarizing layer 20 is de-crosslinked by the crosslinking modification component, the planarizing layer 20 ultimately has a lower (or even no) degree of crosslinking. In some embodiments, this may occur only at or near the boundary of the planarizing layer 20 and the crosslinking modifier layer 18 when, for example, the degree of diffusion of components from one layer to the other is limited. This reduction in the degree of crosslinking may be more pronounced in areas of higher topographical density (e.g., dense regions), where the layer thickness (and, consequently, the concentration of crosslinking agent in the planarizing layer 20 and/or the crosslinking modifier layer 18) is greater as compared to the layer thickness over areas of lower topographical density (e.g., isolated regions).

As a result, the portion of the planarizing layer 20 over the dense region 16a of substrate 10 undergoes less crosslinking (i.e., the crosslinking is more inhibited) than the portion of the planarizing layer 20 over the isolated region 16b. This is due, at least in part, to the larger volume of crosslinking modifier component present in the crosslinking modifier layer 18 (and/or, in some cases, the larger volume of crosslinking agent present in the planarizing layer 20) in the dense region 16a as compared to the isolated region 16b. This may also be due, at least in part, to the increased surface area of the interface between the crosslinking modifier layer 18 and the planarizing layer 20 in the dense region 16a—due to its undulating topography—as compared to the isolated region 16b, which has a more planar topography. Thus, after baking, the dense region 16a has a higher volume of un-crosslinked material in its overlying planarizing layer 20 than in the portion of the planarizing layer 20 overlying the isolated region 16b.

In some embodiments, a solvent can be used to remove (or develop back) some of the planarizing layer 20, thereby reducing its thickness. The develop back step can be carried out by applying a solvent to the planarizing layer 20. Suitable solvents include, but are not limited to, PGMEA, PGME, MIBK, cyclohexanone, ethyl lactate, and combinations thereof. In some cases, the solvent can be the same as the solvent used to form the planarizing composition. Application of the solvent can be by any known method, including puddling. When puddling is used, it may be carried out for a time period of preferably from about 5 seconds to about 100 seconds, and more preferably from about 10 seconds to about 60 seconds, and can be followed by a dry bake at a temperature between about 90° C. and 215° C., more preferably from about 100° C. to about 185° C., or even more preferably from about 150° C. to about 170° C. The bake can be carried out for a time period in the range of preferably from about 30 seconds to about 120 seconds, and more preferably from about 45 seconds to about 75 seconds. The puddling step can be repeated, if desired, prior to the bake step.

Further, because the degree of crosslinking is less in the planarizing layer 20 over the dense region 16a of the substrate 12, the develop back step will remove more planarizing material in the planarization layer 20 over the dense region 16a than it will from the planarization layer 20 over the isolated region 16b. This means that the average thickness of the dense region 16a is reduced more than the average thickness in the isolated region 16b, which reduces or eliminates the bias between the two regions. In some embodiments, after the develop back step, the bias B in the planarizing layer 20 is less than about 30 nm, less than about 25 nm, less than about 20 nm, or less than about 10 nm. In some cases, the bias may be completely removed (e.g., 0 nm), as shown in FIG. 1(D). Thus, no further processing or additional develop back steps are needed for this stack 10 and global planarization of the substrate has been achieved.

In some embodiments, after the develop back step, the planarizing layer 20 includes substantially no regions of un-crosslinked polymer. That is, in some embodiments, at least about 90%, at least about 95%, at least about 99% or all of the total volume of the planarizing layer 20 is crosslinked. This is in contrast to other types of potentially overlying layers (e.g., photoresists) that may be photopatterned and would therefore have regions with and without crosslinking (prior to development). In some embodiments, the planarizing layer covers at least about 90%, at least about 95%, or at least about 99% of the surface of the substrate 12 (or layer disposed thereon) and has not subjected to photo patterning. Rather, such planarizing layers 20 could be used as a base layer for one or more overlying photoresist layers (not shown), which themselves could be photo patterned.

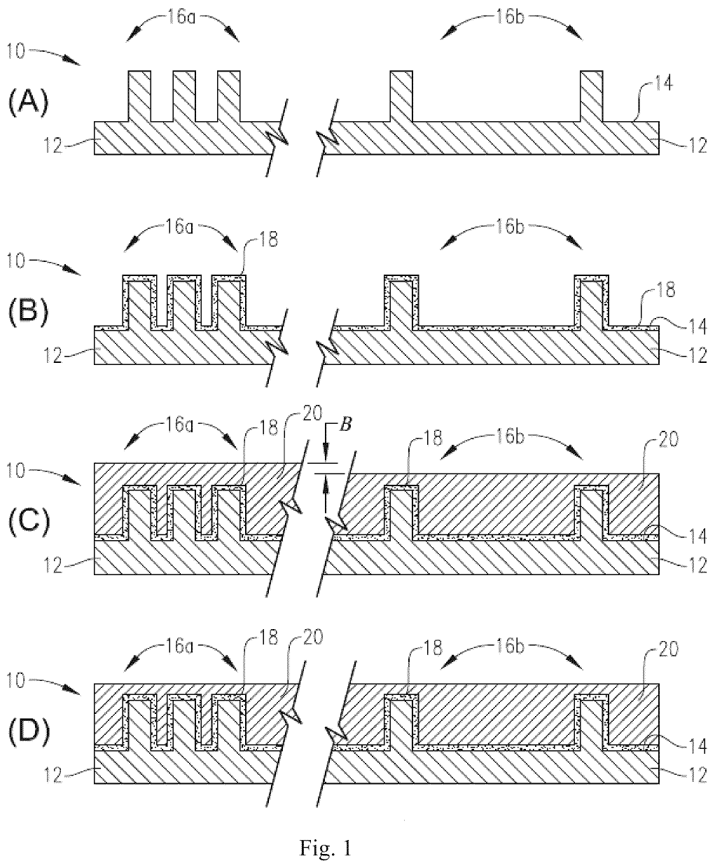

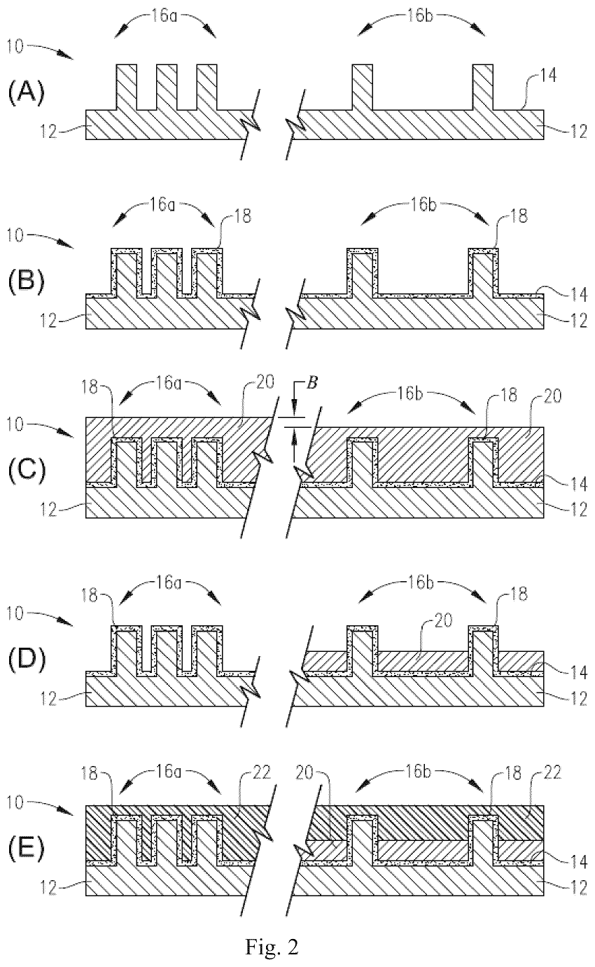

Referring now to FIGS. 2(A) through (E), a similar global planarization method as described with respect to FIGS. 1(A) to 1(D) is shown, with like numerals indicating like parts. The method illustrated in FIGS. 2(A) to 2(C) is the same as that described with respect to FIGS. 1(A) to 1(C).

In some embodiments shown in FIG. 2(D), the develop back step may remove all, or nearly all (not shown), of the planarizing layer from the dense region 16a of topographic figures. As shown in FIG. 2(D), the crosslinking modifier layer 18 may remain, or it may be subsequently reapplied as needed prior to the next processing step. As also shown in FIG. 2(D), a portion of the planarizing layer 20 remains in the isolated region 16b and, as a result, the thickness of the planarizing layer 20 in the isolated region 16b is now greater than the thickness of the planarizing layer 20 in the dense region 16a. Thus, a negative bias of planarizing material has been created in planarizing layer 20.

Next, as shown in FIG. 2(E), a second amount of planarizing composition can be applied to the dense region 16a and the isolated region 16b in a similar manner as described previously to provide a second planarizing layer 22. When some of the first planarizing material remains in the dense region 16a, the second planarizing composition may be applied on the upper surface of that layer. When all of the first planarizing material has been removed from the dense region 16a, the second planarizing composition is applied to the surface 14 of the substrate 12 (or the uppermost surface of the top intermediate layer, if present). The second planarizing composition is applied to the surface of the residual planarizing layer 20 in the isolated region 16b. The second planarizing composition may be the same as or different than the first planarizing composition used to form planarizing layer 20. The second composition, once applied, can be similarly baked and then developed back, as described previously, to provide a final second planarizing layer 22 with little or no bias, as shown in FIG. 2(E).

While it is possible within the scope of the present technology to repeat the additional planarizing step one or more times on top of the second planarizing layer 22, it has been discovered that, in most applications, further planarizing and develop back steps are not needed. Thus, methods according to the present technology are often more time- and cost-efficient than conventional global planarization methods.

In some embodiments, the amount of bias that occurs upon application of the planarizing composition (and/or the amount of negative bias resulting from residual planarizing material in the isolated region as compared to the amount of planarizing material remaining in the dense region after the develop back step) can be adjusted by adjusting the composition of the crosslinking modifier composition and/or the properties of the crosslinking modifier layer 18. Examples of variables that can be adjusted in order to control the thickness and bias of the planarizing layer 20 include, but are not limited to, amount of crosslinking modifier present in the crosslinking modifier layer 18, the thickness of the crosslinking modifier layer 18 and/or planarizing layer 20, the amount of crosslinking agent present in and/or the degree of crosslinking achievable by the planarizing material, and/or the specific baking conditions of one or both of the crosslinking modifier layer 18 and/or the planarizing layer 20.

Significantly, all of the foregoing can be achieved with a single coating step followed by a single bake step. That is, in some embodiments, there is no need for additional coating or baking steps that are often carried out in prior art processes, or the use of multiple planarizing layers as has also been used in prior art processes. Furthermore, there is no need for additional develop-back or polishing, such as CMP, steps that have been required in prior art processes. Thus, these additional steps/processes are preferably avoided, resulting in a less expensive and greatly simplified global planarization process.

Regardless of whether a single-layer or dual-layer planarization method is used, the resulting planarized layer in the stack can be used for additional photolithographic processing. For example, in some embodiments, a photoresist layer can be applied to the uniform planarizing layer directly, with the photoresist layer being patterned according to conventional processes (e.g., exposure to actinic radiation at the wavelength of interest and developing the exposed photoresist). Alternatively, this material can be used as an underlayer (e.g., SOC) material in a trilayer lithography process, with a silicon hardmask as the middle layer and a photoresist as the top layer.

According to embodiments of the present technology, the compositions described herein may be utilized in global planarization applications, which, in some aspects, can be more challenging than local planarization applications. As used herein, the term “local planarization,” refers to planarization of individual features or relatively small groups of features on a given surface, while “global planarization,” refers to planarization of an entire surface (e.g., substrate or one or more intermediate layers thereon). In some embodiments, global planarization may be performed over two or more different types of features, while local planarization may be performed on areas of a substrate or surface only including a single type of feature.

Additional advantages of the various embodiments will be apparent to those skilled in the art upon review of the disclosure herein and the working examples below. It will be appreciated that the various embodiments described herein are not necessarily mutually exclusive unless otherwise indicated herein. For example, a feature described or depicted in some embodiments may also be included in other embodiments but is not necessarily included. Thus, the present disclosure encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone; C alone; A and B in combination; A and C in combination; B and C in combination; or A, B, and C in combination.

The present description also uses numerical ranges to quantify certain parameters relating to various embodiments. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the disclosure. It is to be understood, however, that these examples are provided by way of illustration, and nothing therein should be taken as a limitation upon the overall scope.

### Example 1

### Synthesis of Crosslinking Modifier 1

In this example, a basic polymer crosslinking modifier (Crosslinking Modifier 1) was formed by adding 0.63 grams of 4-vinylpyridine (Sigma-Aldrich, St Louis, MO), 4.81 grams of methyl methacrylate (Monomer Polymer & Dajac Labs, Ambler, PA), 0.78 grams of 2-hydroxyethyl methacrylate (TCI Chemicals, Portland, OR), 0.148 grams of 2,2′-azobis(2-methylpropionitrile) (Sigma-Aldrich, St Louis, MO) and 18.65 grams of PGMEA as a solvent (Fujifilm Ultra Pure Solutions, Inc., Carrollton, TX) to a round-bottomed flask. The contents of the flask were then sparged with Na for 10 minutes and before being heated at 75° C. for 24 hours. The reaction mixture was then cooled, diluted with acetone, and precipitated into about 500 mL of hexanes. The resulting solid was collected by suction and dried at 40° C. under vacuum overnight.

### Example 2

### Synthesis of Crosslinking Modifier 2

In this example, another basic polymer crosslinking modifier (Crosslinking Modifier 2) was formed by adding 0.168 grams of 4-vinylpyridine (Sigma-Aldrich, St Louis, MO), 7.05 grams of methyl methacrylate (Monomer Polymer & Dajac Labs, Ambler, PA), 1.04 grams of 2-hydroxyethyl methacrylate (TCI Chemicals, Portland, OR), 0.197 grams of 2,2′-azobis(2-methylpropionitrile) (Sigma-Aldrich, St Louis, MO) and 24.77 grams of a PGMEA solvent (Fujifilm Ultra Pure Solutions, Inc., Carrollton, TX) to a round-bottomed flask. The contents of the flask were then sparged with N₂ for 10 minutes and before being heated at 75° C. for 24 hours. The reaction mixture was cooled to room temperature and then collected as mother liquor.

### Example 3

### Application of Crosslinking Modifier Layer & Planarizing Layer Thickness Control

Crosslinking Modifier 1 synthesized in Example 1 was dissolved in PGMEA to make a 1.0 weight % solution, which was filtered via a 0.1-mm PTFE filter. The resulting crosslinking modifier composition was applied to two different silicon wafers (Wafer A and B) via spin coating at a ramp rate of 1000 rpm/s, followed by spin-coating at 500 rpm for 60 seconds then at 1500 rpm for 30 seconds. A third wafer (Wafer C) was left uncoated as a control. The coated Wafers A and B were baked at 160° C. for 60 seconds and then rinsed twice with PGMEA via puddling for 20 seconds each. Wafer A was then heated to 160° C. for 60 seconds, and Wafer B was heated to 205° C. for 60 seconds to form a crosslinking modifier layer on each substrate. The final thickness of the crosslinking modifier layer on Wafer A (heated to 160° C.) was 4.4 mm, while the final thickness of the crosslinking modifier layer on Wafer B (heated to 205° C.) was 7.6 mm.

Next, a planarizing composition including 2.0 weight percent epoxy cresol novolac (“ECN,”) resin and TAG2678 in PGMEA (at a ratio of TAG: ECN of 0.03:1) was filtered through 0.1-mm PTFE filter. The resulting planarizing composition was applied to all three wafers (Wafers A to C) by spin-coating at a ramp rate of 1000 rpm/s and at speeds of 500 rpm for 60 seconds, followed by 1500 rpm for 30 seconds and baked at 160° C. for 60 seconds. The resulting planarizing layers were rinsed with PGMEA twice via puddling for 20 seconds each and baked at 160° C. for 60 seconds.

Thicknesses of the planarizing layer before and after washing were measured. Wafer A lost 6.6 nm of planarizing layer thickness, while the thickness of the planarizing layer on Wafer B was reduced by 76.5 nm. Control Wafer C only lost 0.2 nm of planarizing material under the same conditions. The results are summarized in Tables 1a and 1b, below.

TABLE 1a
Crosslinking modifier Layer Properties

| | | | Initial | Rinsing/ | Final |
|---|---|---|---|---|---|
| Wafer | Sample | Baking | Thickness | Drying | Thickness |
| 1 | Base | 160° C./60 s | 43.2 nm | 2 × 20 s | 4.4 nm |
| 2 | Base | 205° C./60 s | 42.4 nm | PGMEA | 7.6 nm |
| | | | | puddle; | |
| | | | | 160° C./60 s | |
| 3 | Control | NA | NA | NA | NA |

TABLE 1b
Planarizing Layer Properties

| | | | Initial | Rinsing | Final |
|---|---|---|---|---|---|
| Wafer | Sample | Sample | Thickness | Drying | Thickness |
| 1 | Base | Planarization | 89.4 nm | 2 × 20 s | 82.6 nm |
| 2 | Base | material | 93.3 nm | PGMEA | 16.8 nm |
| 3 | Control | 160° C./60 s | 85.3 nm | puddle; | 85.1 nm |
| | | | | 160° C./60 s | |

### Example 4

Global Planarization with a Crosslinking Modifier Layer

A chip as illustrated in the lower left (photo image) and right (enlarged plan view) portions of FIG. 4 was used in this trial. The upper left and right portions of FIG. 4 provide cross-sectional SEM images showing a region of dense topographical features (a line-to-pitch ratio of 50:100, or a P of 2:1) and a region of isolated topographical features (a line-to-pitch ratio of 100:500, or a P of 5:1), respectively.

A crosslinking modifier layer was applied to both the dense and isolated regions of the wafer according to the procedure described in Example 3. The wafer was then rinsed with PGMEA via puddling (twice for 20 seconds each) and spun dry at 1500 rpm for 60 seconds before being baked at 160° C. for 60 seconds to form the crosslinking modifier layer. Next, the planarizing material was applied to each substrate as described in Example 3 before being washed with PGMEA (twice for 20 second each via puddling), spin drying at 1500 rpm for 60 seconds, and baking at 160° C. for 60 seconds.

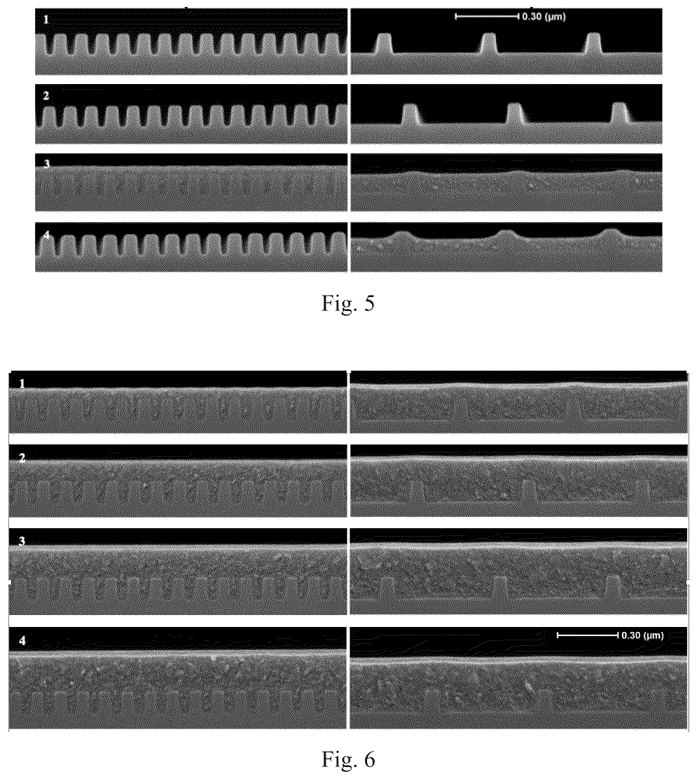

SEM cross-sections of the dense and isolated topographic regions of the substrate at various points during the above procedure are shown in FIG. 5. Specifically, the top image (Image 1) shows the initial condition of the wafer, while the next image (Image 2) shows the wafer with the conformal crosslinking modifier layer after baking. The crosslinking modifier layer in Image 2 is about 4 nm thick and not able to be seen. Image 3 shows the wafer after application of the planarizing material but prior to any planarizing steps. Thus, the coating on the dense region (left) is thicker than that on semi-dense (iso) region (right). In other words, gap-filling bias appears. Image 4 shows the wafer after the develop back step (e.g., washing of the planarizing layer with a solvent). As shown in Image 4, more gap-fill materials are removed in dense region than in semi-dense (iso) region, which results in a reverse gap-fill bias (e.g., more planarizing material removed from the dense region than the isolated region). The coated substrate in Image 4 is now ready for application of another planarizing layer, thereby reducing the reverse bias between the dense and isolated regions as shown in Image 4 of FIG. 5. An example of an additional when another gap-fill coating is applied, dense region planarization can be achieved, as demonstrated in Example 5, below.

### Example 5

Global Planarization with a Develop Back Step

Three silicon wafers having regions of both dense and isolated topographic features were coated with a crosslinking modifier layer as described in Example 4. Another similar wafer was not coated with the crosslinking modifier. All wafers were then coated with planarizing compositions formulated with different amounts of ECN to achieve different thicknesses. All planarizing compositions included TAG2678 at a 0.02:1 ratio with ECN, and all included PGMEA as the solvent. The planarizing compositions were applied to each wafer via spin coating at a ramp rate of 1000 rpm/s then at 500 rpm for 60 seconds followed by 1500 rpm for 60 seconds, and a bake at 160° C. for 60 seconds. The planarizing layers were then rinsed with PGMEA (twice for 20 second each via puddling), spin drying at 1500 rpm for 60 seconds, and baking at 160° C. for 60 seconds. SEM cross sections of each of the coated wafers are provided in FIG. 6, with the substrate number in the top left corner of each image. The bias of each was calculated and the results are summarized in Table 2, below.

TABLE 2

| | Planarizing | | |
|---|---|---|---|
| | Composition | | Bias |
| | ECN, | TAG:ECN | (Dense − Iso), |
| Substrate | wt % | Ratio | nm |
| 1 | 2 | 0.02:1 | −19.6 |
| 2 | 3 | 0.02:1 | −12.8 |
| 3 | 4 | 0.02:1 | −3.8 |
| 4 | 5 | 0.02:1 | +43.4 |

As shown in FIG. 6, the positive bias of Substrate 4 (control) is the result of a greater accumulation of planarizing material in the dense region of the wafer. Without the crosslinking modifier layer, the develop back step had essentially no effect on the planarizing layer of Substrate 4. In contrast, each of Substrates 1-3 (disclosed) included a crosslinking modifier layer underlying the planarizing layer and were able to remove the positive bias during the develop back step. The negative biases for each of Substrates 1-3 indicate that the bias reduction step was slightly overdone, resulting in slightly thicker planarizing layer in the isolated region of the wafer.

### Example 6

Double-Layer Planarization with Different Bake Temperatures

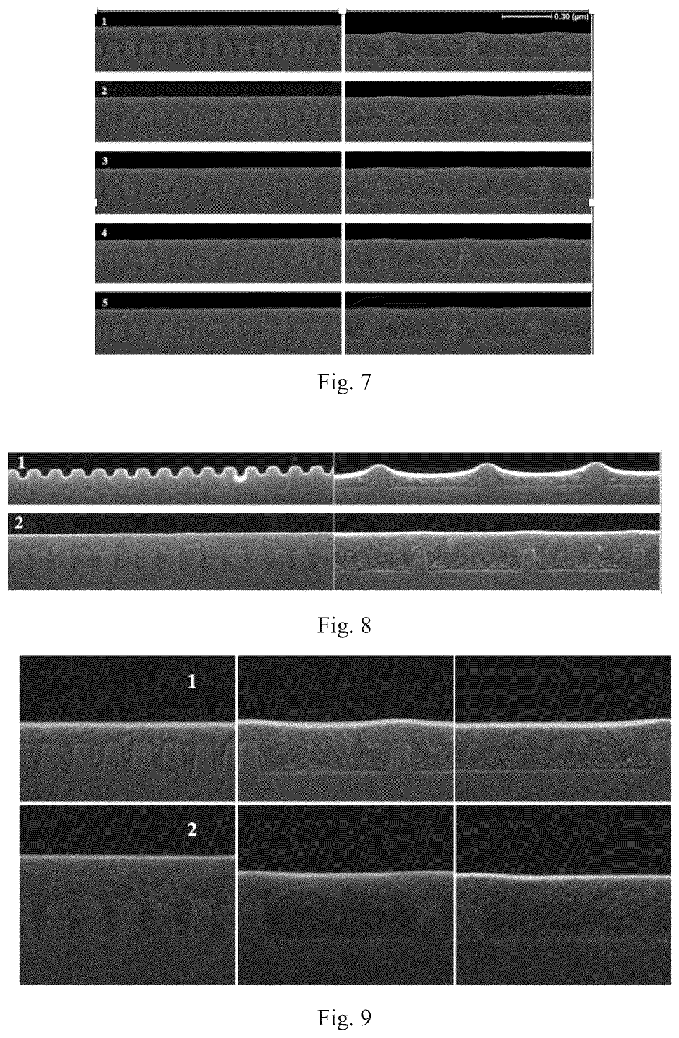

Five additional silicon wafers with regions of dense and isolated topography were coated with a crosslinking modifier layer and a first planarizing layer as described previously in Example 5. The planarizing layer was also subjected to a develop back (wash) step as also described in Example 5. A second planarizing composition, including 3 wt % ECN with TAG2678 in a ratio of 0.03:1 TAG: ECN in PGMEA, was filtered via a 0.1-μm PTFE filter, and applied on top of the first planarizing layer under the same spin coating conditions as the first planarizing layer. The second planarizing layer was also rinsed with PGMEA (twice for 20 second each via puddling) before being subjected to spin drying at 1500 rpm for 60 seconds and baking at 205° C. for 60 seconds. The bias of the second planarizing layer between the dense and isolated regions was measured for each substrate. The results are summarized in Table 3, below. SEM cross sections of each wafer are provided in FIG. 7.

TABLE 3

| | | 1^{st} | 1^{st} | 2^{nd} | |
|---|---|---|---|---|---|
| | Surface Base | Planarization | Planarization | Planarization | Dense/iso bias |
| Substrate | Modification | Bake | Wash | Bake | (nm) |
| 1 | 2 × 20-s | 155° C., 60 s | 2 × 20 s | 205° C., 60 s | 51.2 |
| 2 | PGMEA puddle | 160° C., 60 s | PGMEA puddle | | 7.5 |
| 3 | 160° C., 60-s | 160° C., 60 s | 160° C., 60 s bake | | 3.8 |
| 4 | bake | 160° C., 60 s | | | 7.5 |
| 5 | | 165° C., 60 s | | | 0 |

### Example 7

Double-Layer Planarization with Spin-on Carbon (SOC)

Crosslinking Modifier 2 synthesized in Example 2 was dissolved in PGMEA to make a 2.0 weight % solution, which was filtered via a 0.2-mm PTFE filter. The resulting crosslinking modifier composition was applied to two silicon wafers each having dense and isolated topography regions as described in Example 3. Next, a layer of OptiStack® SOC110E-311, a SOC material (commercially available from Brewer Science Inc.) was applied to the upper surface of the crosslinking modifier layer via spin coating at 1500 rpm for 60 seconds and was baked at 205° C. for 60 seconds. The resulting planarizing layer had a thickness of 110 nm. After baking, the planarizing layer was washed with PGMEA as described previously in Example 3, except the layer was baked at 155° C. instead of 160° C. for 60 seconds.

A second layer of the same SOC planarizing composition was applied to one of the wafers according to the procedure described in Example 6, except the baking was performed at 205° C. for 60 seconds. The other wafer was not further coated with a second SOC planarizing layer. FIG. 8 provides SEM cross-sectional images of the wafers with (bottom) and without (top) the second planarizing layer.

### Example 8

Single-Layer Planarization with SOC

A silicon wafer with areas of dense and isolated topography were coated with a crosslinking modifier layer and a first layer of SOC planarizing material as described in Example 7. The thickness of the first planarizing layer was 170 nm. After the initial bake step, the planarizing layer was washed with PGMEA via puddling (twice for 20 second each) and then baked at 160° C. for 120 seconds. A control wafer with similar topographic regions was coated with the SOC planarizing material only at a ramp rate of 1000 rpm/s, then 1500 rpm for 60 seconds before being baked at 205° C. for 160 seconds. SEM cross sectional images are provided in FIG. 9, with the disclosed wafer images at the top and the control wafer images at the bottom.

### Example 9

### Development of Equations to Predict of Layer Thickness & Bias

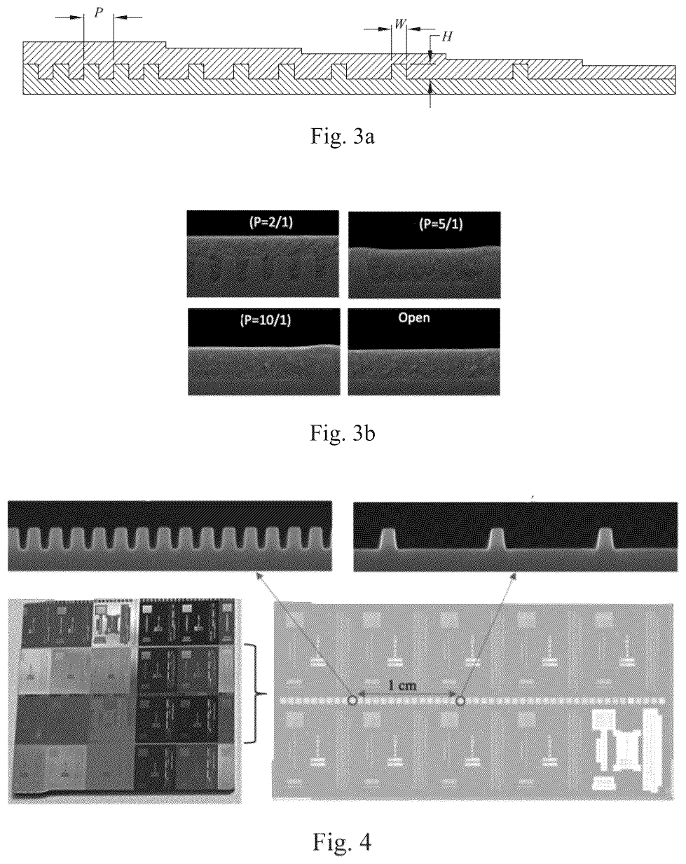

Equations (1) and (2), below, for predicting the bias resulting from application of planarizing material to certain substrates were tested. These equations assume that the total amount of planarizing material is the same in any given region of the substrate and that there is no long-distance material flow (only local):

$$surface ratio = \frac{2}{W} \times \frac{H}{P} + 1 \qquad ( Equation 1 )$$

$$predicted bias = \frac{H}{P} \qquad ( Equation 2 )$$

wherein H is the line height, W is the line width, and P is the pitch/line, as generally shown in FIG. 3a. As used herein, the term “surface ratio” refers to the total surface area of a given region divided by its open area. Further, the above Equations (1) and (2) assume that the bias originates from lines occupying the space and would not necessarily apply to other types of topographic features.

The results comparing the calculated and measured bias values for several different topographical regions, as compared to a fully open region, as shown in FIG. 3b, are summarized in Table 4, below.

TABLE 4

| | | Calculated | Measured |
|---|---|---|---|
| Pitch/Line | Surface Ratio | Bias, nm | Bias, nm |
| 2 | 2.5 | 45 | 43 |
| 5 | 1.6 | 18 | 19 |
| 10 | 1.3 | 9 | 11 |

1. A method for forming a structure, said method comprising:
providing a substrate comprising a substrate surface;
optionally forming one or more intermediate layers on said substrate surface, wherein said substrate surface, or an uppermost surface of a top intermediate layer on said substrate surface if said one or more intermediate layers are present, comprises a first region of dense topographic features and a second region of isolated topographic features;
applying a crosslinking modifier composition to said substrate surface or to said uppermost surface of said top intermediate layer, if present, to form a crosslinking modifier layer, said crosslinking modifier layer covering at least a portion of said first region of dense topographic features and at least a portion of said second region of isolated topographic features;
applying a planarizing composition on said crosslinking modifier layer;
heating said planarizing composition to form a planarizing layer having a first average thickness in said first region of dense topographic features and a second average thickness in said second region of isolated topographic features; and
contacting said planarizing layer with a solvent to reduce said first average thickness and said second average thickness, wherein said contacting reduces the first average thickness more than said second average thickness.

2. The method of claim 1, wherein said crosslinking modifier composition comprises a polymer dispersed or dissolved in a solvent system, said polymer being present in said crosslinking modifier composition in an amount of about 1% to about 10%, based on the total weight of the crosslinking modifier composition taken as 100%.

3. The method of claim 1, wherein said planarizing composition comprises an acid crosslinkable polymer and said crosslinking modifier composition comprises at least one base-generating polymer.

4. The method of claim 3, wherein said base-generating polymer comprises between about 1.5% and about 12.5% by weight of a base-generating monomer, based on the total weight of said polymer taken as 100%.

5. The method of claim 3, wherein said base-generating polymer comprises between about 5% and about 15% by weight of a surface adhesion monomer, based on the total weight of said polymer taken as 100%.

6. The method of claim 3, wherein said base-generating polymer comprises between about 70% and about 90% by weight of a solubility-enhancing monomer, based on the total weight of said polymer taken as 100%.

7. The method of claim 3, wherein said base-generating polymer is formed from recurring monomers of 2-hydroxyethylmethacrylate, 4-vinylpyridine, and methyl methacrylate.

8. The method of claim 1, further comprising heating said crosslinking modifier composition after said applying to form said crosslinking modifier layer, wherein said heating is carried out at a temperature of about 150° C. to about 215° C. for a time period of about 45 to about 75 seconds.

9. The method of claim 1, wherein said planarizing composition comprises a spin-on carbon composition.

10. The method of claim 1, wherein after said heating and prior to said contacting, said planarizing layer has a bias measured between said first region of dense topographic features and said second region of isolated topographic features of least 35 nm.

11. The method of claim 10, wherein after said contacting, said planarizing layer has a bias measured between said first region of dense topographic features and said second region of isolated topographic features of not more than 10 nm.

12. The method of claim 1, further comprising after said contacting, applying a second planarizing composition to an upper surface of said planarizing layer in said second region and to said surface of said substrate, said uppermost intermediate layer, if present, and/or said planarizing layer, if present; heating said second planarizing composition to form a second planarizing layer; and contacting said second planarizing layer with a solvent, wherein said second planarizing layer has a bias measured between said first region of dense topographic features and said second region of isolated topographic features less than about 10 nm after said contacting.

13. The method of claim 12, wherein said second planarizing composition is different than said planarizing composition applied to said crosslinking modifier layer.

14. A method of forming a structure, said method comprising:
optionally forming one or more intermediate layers on a surface of a substrate, wherein said substrate surface, or an uppermost surface of a top intermediate layer on said substrate surface if said one or more intermediate layers are present, comprises a first region of dense topographic features and a second region of isolated topographic features;
forming a crosslinking modifier layer on said substrate surface or on said uppermost surface of said top intermediate layer, if present, said crosslinking modifier layer:
covering at least a portion of said first region of dense topographic features and at least a portion of said second region of isolated topographic features; and
comprising at least one polymer capable of generating a crosslinking modification component;
applying a planarizing composition on said crosslinking modifier layer, said planarizing composition comprising one or both of a crosslinkable polymer or a de-crosslinkable polymer; and
heating said planarizing composition to form a planarizing layer on said crosslinking modifier layer, wherein during said heating, the crosslinking modification component is generated within said crosslinking modifier layer, and at least some of said crosslinking modification component contacts said planarizing layer during and/or after said heating, and wherein said crosslinking modification component contacting said planarizing layer:
(1) decreases the degree of crosslinking that said crosslinkable polymer would have undergone during said heating if said crosslinking modification component were not generated in said crosslinking modifier layer; and/or
(2) de-crosslinks at least some of said de-crosslinkable polymer in said planarizing layer.

15. The method of claim 14, wherein said planarizing layer has a first average thickness in said first region of dense topographic features and a second average thickness in said second region of isolated topographic features, and further comprising contacting said planarizing layer with a solvent to reduce said first average thickness and said second average thickness, wherein said first average thickness is reduced more than said second average thickness.

16. The method of claim 15, wherein after the contacting, said planarizing layer has a bias measured between said first region of dense topographic features and said second region of isolated topographic features of not more than 30 nm.

17. The method of claim 14, wherein said crosslinking modification component comprises a base and said crosslinking modification component decreases the degree of crosslinking that said crosslinkable polymer would have undergone during said heating if said crosslinking modification component were not present in said crosslinking modifier layer.

18. The method of claim 14, wherein said polymer capable of generating said crosslinking modification component comprises a base-generating polymer.

19. The method of claim 18, wherein said base-generating monomer comprises a monomer comprising at least one base-generating group bonded thereto, and wherein said base-generating group is chosen from one or more of aliphatic amines, aromatic amines, heterocyclic amines, or mixtures thereof.

20. The method of claim 14, wherein said crosslinking modification component comprises an acid and said crosslinking modification component de-crosslinks at least some of said de-crosslinkable polymer in said planarizing layer.

21. The method of claim 14, wherein said polymer capable of generating said crosslinking modification component in said crosslinking modifier layer comprises an acid-generating polymer.

22. The method of claim 21, wherein said acid-generating polymer comprises at least one monomer having an acid-generating group bonded thereto, wherein said acid-generating group is chosen from a photoacid generator group or a thermal acid generator group.

23. The method of claim 14, wherein said polymer capable of generating said crosslinking modification component comprises at least one solubility-enhancing monomer and at least one surface adhesion monomer.

24. The method of claim 14, wherein said forming comprises heating said crosslinking modifier composition to form said crosslinking modifier layer, wherein said heating is carried out at a temperature of about 150° C. to about 215° C. for a time period of about 45 to about 75 seconds.

25. The method of claim 14, wherein at least some of the crosslinking modification component diffuses into the planarizing layer during and/or after said heating.

26. The method of claim 25, wherein said planarizing layer comprises a crosslinkable polymer and a crosslinking agent, wherein said crosslinking modification component that diffuses into said planarizing layer and reacts with at least a portion of the crosslinking agent to decrease the degree of crosslinking that said crosslinkable polymer would have undergone during said heating if said crosslinking modification component were not generated in said crosslinking modifier layer.

27. The method of claim 25, wherein said crosslinking modification component that diffuses into said planarizing layer de-crosslinks at least some of said de-crosslinkable polymer in said planarizing layer.

28. The method of claim 14, wherein said planarizing layer comprises a crosslinkable polymer and a crosslinking agent, wherein during said contacting, at least a portion of said crosslinking agent diffuses into said crosslinking modifier layer and reacts with at least a portion of said crosslinking modification component, and wherein said crosslinking modification component contacting said planarizing layer decreases the degree of crosslinking that said crosslinkable polymer would have undergone during said heating if said crosslinking modification component were not generated in said crosslinking modifier layer.
